(19) United States
(12) Patent Application Publication
(10) Pub. No.: US 2015/0206595 A1
(43) Pub. Date: Jul. 23, 2015

(54) ANTIFUSE ARRAY ARCHITECTURE

(71) Applicant: SK hynix Inc., Gyeonggi-do (KR)

(72) Inventor: Jae-Hong JEONG, Gyeonggi-do (KR)

(21) Appl. No.: 14/308,363

(22) Filed: Jun. 18, 2014

(30) Foreign Application Priority Data
Jan. 22, 2014 (KR) 10-2014-0007621

(51) Int. Cl. G11C 17/16; G11C 17/18

(52) U.S. Cl. CPC G11C 17/16; G11C 17/18

(57) ABSTRACT

An anti-fuse including a program transistor which can be short-circuited depending on whether the program transistor is programmed, and also including a read transistor which is coupled with the program transistor and a bit line, and outputs information to the bit line based on whether the program transistor is short-circuited, comprising: an active region formed in a first direction in a semiconductor substrate; a bit line contact formed over the active region and coupled with the bit line; a program gate electrode the entire or part of which is buried in the active region over the program transistor; and a read gate electrode disposed over the read transistor and formed between the program gate electrode and the bit line contact.

### CROSS-REFERENCE TO RELATED APPLICATIONS

The present application claims priority of Korean Patent Application No. 10-2014-0007621, filed on Jan. 22, 2014, which is incorporated herein by reference in its entirety.

### BACKGROUND

1. Field

Exemplary embodiments of the present invention relate to an antifuse array including a plurality of antifuses, and more particularly, to an antifuse array that occupies a reduced area.

2. Description of the Related Art

Semiconductor integrated circuits have fuse circuits. A fuse circuit is a circuit that inverts a previous option signal through a fuse programming method and outputs an inverted option signal. The fuse circuit is used to selectively provide an option signal in a voltage control circuit and a redundancy circuit. Fuse programming methods are generally divided into laser blowing and electrical methods. In the laser blowing method, the connection state of a fuse is cut using a laser beam. The physical fuse programming method may be performed in the wafer stage before the semiconductor integrated circuit is packaged. On the other hand, the electrical fuse programming method performs a program and can change the connection state of a fuse in the package stage. Among the fuses used for the electrical fuse programming method is an anti-fuse.

An anti-fuse utilizes a concept opposite to that of a fuse. An anti-fuse is initially set to a disconnection state and then, after being packaged, the anti-fuse is switched into a connection state based on a program. In the initial stage of fabrication, the anti-fuse is in an insulator state and has a high resistance, over one-million ohms. The anti-fuse may be changed into a conductor having a low resistance, in the hundreds of ohms or less, based on a program. The physical change of the anti-fuse is made by applying a voltage over a predetermined level, which is referred to as a program voltage, to the space between electrodes, which are two conductive layers, to break the insulator down into a conductor. In this manner, conventional anti-fuse circuits may be programmed when the semiconductor integrated circuit is in the packaged state.

Semiconductor memory devices are becoming further and further integrated and researchers as well as industry are trying hard to reduce the total area that semiconductor memory devices occupy to improve productivity. As the area of semiconductor memory devices becomes smaller, the number of semiconductor memory devices that may be produced from one wafer may be increased, which leads to improved productivity and reduced production cost. However, since the storage capacity of semiconductor memory devices is increasing, the number of unit cells has also increased. This means that the size of the redundancy circuit for substituting defective unit cells is growing as well, making it difficult to reduce the total area occupied by the semiconductor memory device. To alleviate this concern, redundancy circuits have adopted a matrix-type anti-fuse array. A redundancy circuit using a matrix-type anti-fuse array is small compared to redundancy circuits using a metal fuse. Additionally, redundancy circuits having a matrix-type anti-fuse array may be formed through a general CMOS process. These are some of the advantages of a redundancy circuit that utilizes a matrix-type anti-fuse array.

Since an anti-fuse array includes many anti-fuses, the redundancy circuit occupies a large area in the semiconductor integrated circuit, which is disadvantageous.

### SUMMARY

An embodiment of the present invention is directed to an anti-fuse having a gate electrode structure that may contribute to reducing the area of an anti-fuse array having a plurality of anti-fuses.

In accordance with an embodiment of the present invention, an anti-fuse may include a program transistor that is short-circuited when the program transistor is programmed; a read transistor coupled to a bit line and the program transistor, that outputs information to the bit line that is based on whether the program transistor is short-circuited (short circuit info ation); an active region formed in a semiconductor substrate; a bit fine contact formed over the active region and coupled with the bit line; a program gate electrode that is partially or entirely buried in the active region over the program transistor; and a read gate electrode disposed over the read transistor and formed between the program gate electrode and the bit line contact.

In accordance with another embodiment of the present invention, an anti-fuse may include a program transistor which can be short-circuited depending on whether the program transistor is programmed; a read transistor which is coupled with a bit line and the program transistor and outputs information based on whether the program transistor is short-circuited; an active region formed in a semiconductor substrate; a bit line contact formed over the active region and coupled with the bit line; a program gate electrode that is partially or entirely buried in the active region over the program transistor; and a read gate electrode disposed over the read transistor and formed between the program gate electrode and the bit line contact where part or the entire read gate electrode is buried in the active region.

In accordance with yet another embodiment of the present invention, an anti-fuse array may include a plurality of program lines and a plurality of read lines that are arranged in the form of a matrix with a plurality of bit lines; first and second program transistors that are respectively coupled with the program lines and can be short-circuited depending on whether the first and second program transistors are programmed; first and second read transistors that are respectively coupled with the read lines, and disposed between the bit lines and the first and second program transistors, and output information to the bit lines based on whether the first and second program transistors are short-circuited; active regions formed in a first direction in a semiconductor substrate; bit line contacts formed over the active regions and coupled with the bit lines; first and second program gate electrodes that are formed over the first and second program transistors to confront the bit line contacts, where each program gate electrode is partially or entirely buried in the corresponding active region; a first read gate electrode disposed over the first read transistor and formed between the first program gate electrode and a bit line contact; and a second read gate electrode disposed over the second read transistor and formed between the second program gate electrode and the bit line contact.

In accordance with still another embodiment of the present invention, an anti-fuse array may include a plurality of program lines and a plurality of read lines that are arranged in a matrix with a plurality of bit lines; first and second program transistors that are respectively coupled with the program lines and can be short-circuited depending on whether the first and second program transistors are programmed; first and second read transistors that are respectively coupled with the read lines, disposed between the bit lines and the first and second program transistors, and output information based on whether the first and second program transistors are short-circuited to the bit lines; active regions formed in a first direction in a semiconductor substrate; bit line contacts formed over the active regions and coupled with the bit lines; first and second program gate electrodes that are formed over the first and second program transistors to confront the bit line contacts, where each program gate electrode is partially or entirely buried in a corresponding active region; a first read gate electrode disposed over the first read transistor and formed between the first program gate electrode and a bit line contact, where the first read gate electrode is partially or entirely buried in a corresponding active region; and a second read gate electrode disposed over the second read transistor and formed between the second program gate electrode and the bit line contact, where the second read gate electrode is partially or entirely buried in the corresponding active region.

### BRIEF DESCRIPTION OF THE DRAWINGS

FIG. 1 is a circuit diagram illustrating an anti-fuse array including a plurality of anti-fuses.

FIG. 2A is a plan view illustrating a first anti-fuse and a second anti-fuse that share a bit line in FIG. 1.

FIG. 2B is a plan view illustrating an anti-fuse array including the first anti-fuse and the second anti-fuse.

FIG. 3 is a perspective view of an anti-fuse in accordance with a first embodiment of the present invention.

FIG. 4 is a perspective view of an anti-fuse array including the anti-fuse shown in FIG. 3.

FIG. 5 is a perspective view of an anti-fuse in accordance with a second embodiment of the present invention.

FIG. 6 is a perspective view of a portion of an anti-fuse array that includes the anti-fuse shown in FIG. 5.

FIG. 7 is a perspective view of a plurality of anti-fuse arrays to which a gate structure of an embodiment of the present invention is applied.

FIG. 8 is a plan view of the anti-fuse arrays shown in FIG. 7.

### DETAILED DESCRIPTION

Exemplary embodiments of the present invention will be described below in detail with reference to the accompanying drawings. The present invention may, however, be embodied in different forms and should not be construed as limited to the embodiments set forth herein. Rather, these embodiments are provided so this disclosure will be thorough and complete, and will fully convey the scope of the present invention to those skilled in the art. Throughout the disclosure, like reference numerals refer to like parts in the various figures and embodiments.

The drawings are not necessarily to scale and proportions may have been exaggerated to clearly illustrate features of the embodiments. When a first layer is referred to as being on a second layer or “on” a substrate, it not only refers to where the first layer is formed directly on the second layer or the substrate, but also to where a third layer exists between the first layer and the second layer or the substrate.

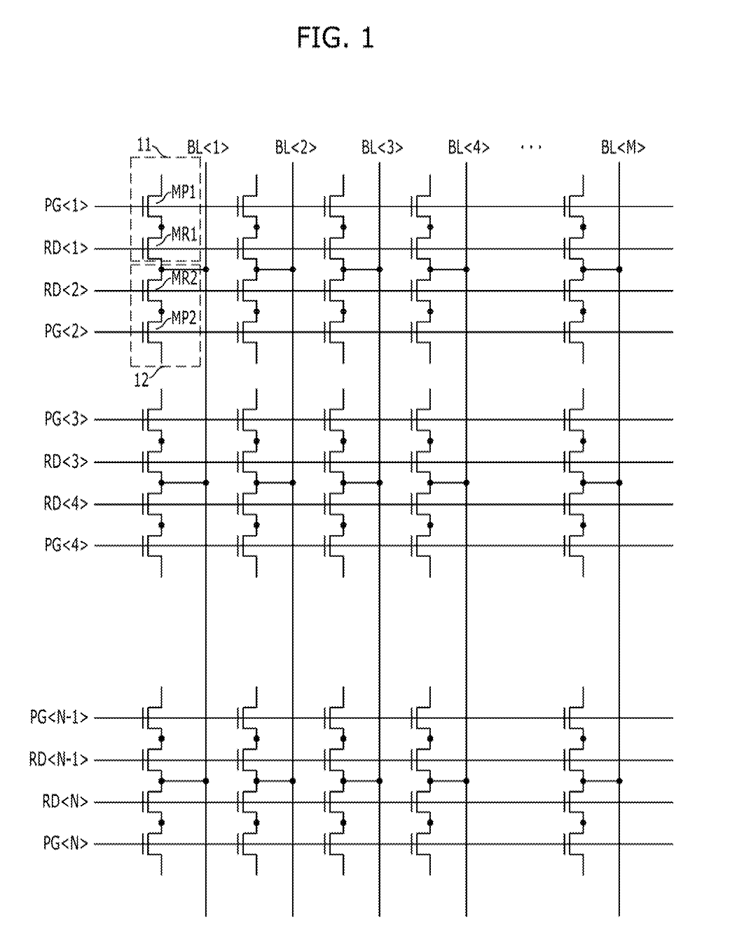

FIG. 1 is a circuit diagram illustrating an anti-fuse array including a plurality of anti-fuses.

Referring to FIG. 1, the anti-fuse array includes a plurality of anti-fuses that are arranged in N rows and M columns. In the anti-fuses of the anti-fuse array, a plurality of program lines PG<1:N> and read lines RD<1:N> are arranged in the form of matrix with a plurality of bit lines BL<1:M>. The anti-fuse array shares bit lines and includes a first anti-fuse 11 and a second anti-fuse 12 that are formed confronting the bit line.

Hereafter, only the first anti-fuse 11 is representatively described since the anti-fuses have the same structure. The first anti-fuse 11 includes a program transistor MP1 and a read transistor MR1. Whether the program transistor MP1 is open or not is decided based on whether it is programmed. The program transistor MP1 has characteristics of a resistor or a capacitor depending on whether it is ruptured (i.e. broken down, programmed, short-circuited). The program transistor MP1 may be regarded as a resistive memory device that stores data based on its level of resistance. The read transistor MR1 is coupled with a bit line BL<1> and the program transistor MP1 to electrically connect the program transistor MP1 and the bit line BL<1> under the control of the read lines RD<1> and outputs information to the bit line BL<1> based on whether the program transistor MP1 is open.

Hereafter, a program operation is described based on the assumption that the first row is the selected row and the first column is the selected column.

The read line RD<1> of the selected row is enabled, and the other read lines are disabled. Thus, the read transistor MR1 is turned on, and the other read transistors are turned off. To program transistor MP1 of the selected row, a voltage high enough to destroy the gate insulation layer of the anti-fuse is applied, while a low voltage, e.g. a ground voltage, is applied to the other program transistors. The high voltage is generally generated by pumping a power source voltage. The selected bit line BL<1> is coupled with a data access circuit (not shown), and the unselected bit lines float. When the input data is program data (e.g., ‘1’), the data access circuit (not shown) drives the selected bit line BL<1> at a low level so that the program transistor of the selected anti-fuse is programmed (ruptured). When the input data is not program data (e.g., ‘0’), the data access circuit (not shown) drives the selected bit line BL<1> at a high level so that the program transistor of the selected anti-fuse is not programmed (not ruptured). Since the unselected bit lines float, the program transistors are not programmed although high voltage is applied to the gates of the program transistors.

Hereafter, a read operation is described. The read line RD<1> of the selected row is enabled, and the other read lines are disabled. Thus, the read transistor is turned on, and the other read transistors are turned off. To a program line of the selected row, a voltage appropriate for the read operation (which is generally, a power source voltage) is applied, and a low voltage (e.g., a ground voltage) is applied to the other program lines. The selected bit line is coupled with the data access circuit, and the unselected bit lines float. When current flows in the selected bit line, the data access circuit recognizes that the program register is programmed (which means that the data access circuit recognizes the data of the anti-fuse as ‘1’). When current does not flow in the selected bit line, the data access circuit recognizes that the program register is not programmed. Therefore, whether a program transistor is short-circuited or not may be known from the on/off state of a read transistor.

Hereafter, a concern in a typical anti-fuse array is described with reference to the plan view of the first anti-fuse 11 and the second anti-fuse 12 that share a bit line.

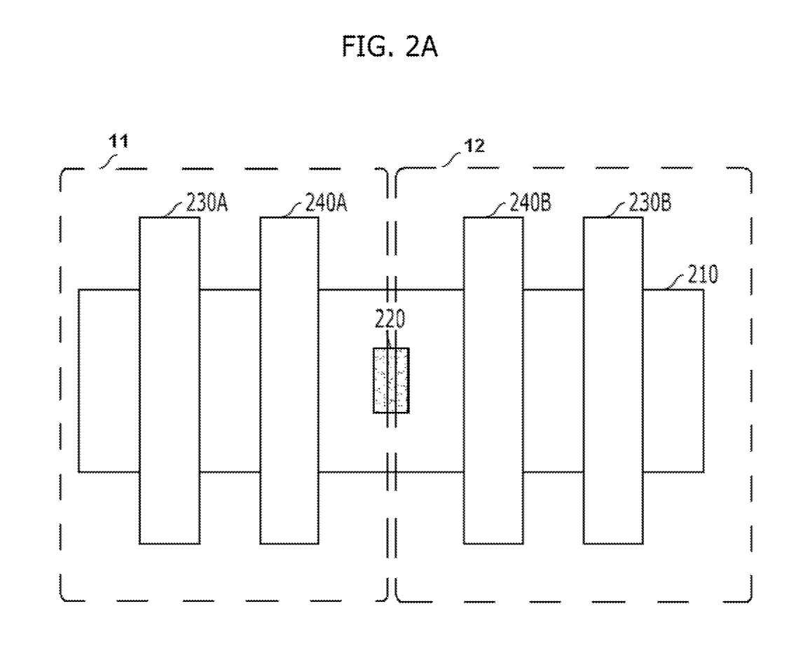

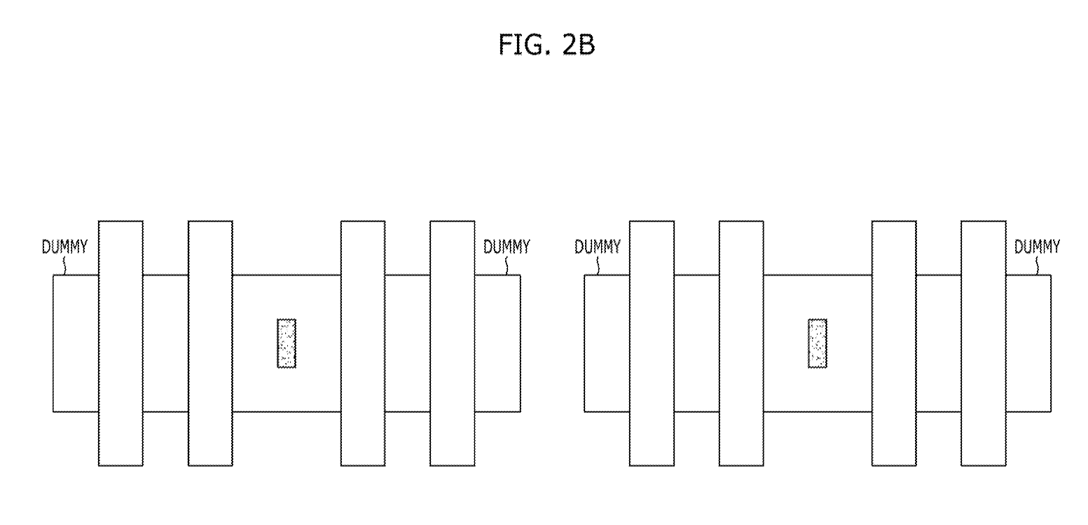

FIG. 2A is a plan view illustrating the first anti-fuse 11 and the second anti-fuse 12 that share a bit line in FIG. 1, and FIG. 2B is a plan view illustrating the anti-fuse array including the first anti-fuse 11 and the second anti-fuse 12.

Referring to FIG. 2A, an active region 210 is defined in a semiconductor substrate (not shown), and a bit line contact 220, first and second program gate electrodes 230A and 230B, and first and second read gate electrodes 240A and 240B are formed over the active region 210.

The first and second program gate electrodes 230A and 230B are disposed over a program transistor, and the first and second read gate electrodes 240A and 240B are disposed over a read transistor. In the active region 210 of the semiconductor substrate, source-drain regions of first and second program transistors and first and second read transistors are formed. A gate insulation layer is formed between the first and second program gate electrodes 230A and 230B and the semiconductor substrate and between the first and second read gate electrodes 240A and 240B and the semiconductor substrate. To be specific, the source regions of first and second read transistors are coupled with bit lines, and the drain regions of the first and second read transistors are coupled with one-side of first and second program transistors. The other-side of the first and second program transistors are coupled with source regions, which become dummy active regions after going through a Shallow Trench Isolation (STI) process.

Referring to FIG. 2B, which is a plan view of the anti-fuse array including the first anti-fuse 11 and the second anti-fuse 12, the typical anti-fuse array has a limitation terms of area because of the presence of dummy active regions.

Also, since a channel has to be formed in the lower portion of a gate electrode, the anti-fuses have to be secured with an area where the source and drain regions overlap with the gate electrodes. In other words, in typical anti-fuses, the edges of the active region overlap with the gate electrode. In this method, the overlapping area may be secured by increasing the size (the width or length) of the gate electrode region, but this has a drawback of increasing the area of the anti-fuse array.

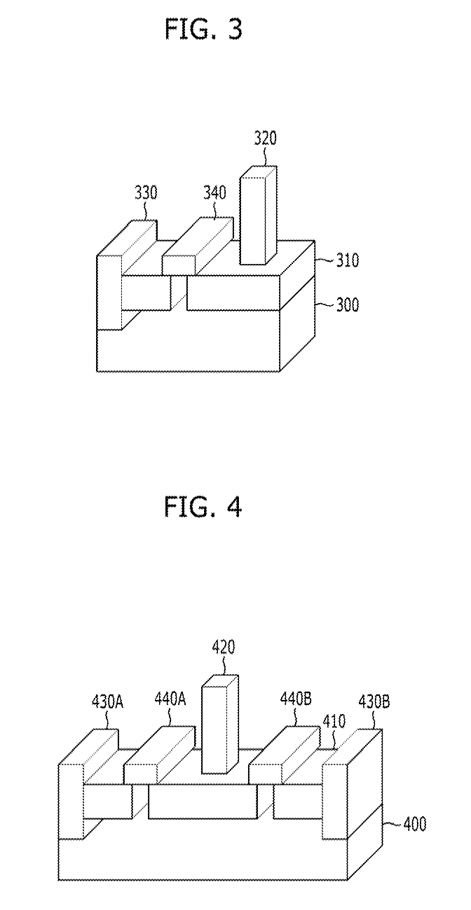

FIG. 3 is a perspective view of an anti-fuse in accordance with a first embodiment of the present invention.

Referring to FIG. 3, the anti-fuse may include an active region 310, a bit line contact 320, a program gate electrode 330, and a read gate electrode 340.

The active region 310 may be formed in a semiconductor substrate 300. The bit line contact 320 is formed over the active region 310 to be coupled with a bit line. The program gate electrode 330 is provided over a program transistor (not shown), and the program gate electrode 330 may be formed to be entirely or partially buried in the active region 310. A structure where the entire program gate electrode 330 is buried in the active region 310 is called a buried gate structure, and a structure where a portion of the program gate electrode 330 is buried in of the active region 310 is called a recess gate structure. The program gate electrode 330 is coupled with a program line and receives a program voltage. The read gate electrode 340 is formed over a read transistor between the program gate electrode 330 and the bit line contact 320. The read gate electrode 340 is coupled with a read line and receives a read voltage. Although not illustrated in the drawing, a gate insulation layer may be formed between the program gate electrode 330 and a neighboring active region and between the surface of the semiconductor substrate 300 and the read gate electrode 340.

As described earlier, a program operation may be performed as the gate insulation layer between the program gate electrode 330 and the active region 310 is ruptured by applying a high program voltage through the program gate electrode 330. Subsequently, when a voltage is applied to turn on the read gate electrode 340, a channel region through which electrons may move between a source region and a drain region is formed. In other words, electric current is generated in the channel region. The generated current is applied to the bit line contact 320, and whether the program transistor is programmed may be known from the current passing from the bit line contact 320 to the bit line.

The anti-fuse in accordance with the first embodiment of the present invention has a structure where the gate electrode region is buried in of the active region 310. The gate electrode region blocks off the edges of the active region 310. Since an anti-fuse of this structure may increase the area of the gate electrode region without increasing the area of the channel region for programming, the performance of a program operation may be improved. The buried gate structure may also decrease the area of an anti-fuse array including the anti-fuse in accordance with the first embodiment of the present invention.

FIG. 4 is a perspective view of an anti-fuse array including the anti-fuse shown in FIG. 3.

As described earlier with reference to FIG. 1, the anti-fuse in array may include a first anti-fuse and a second anti-fuse that are disposed confronting each other around a shared bit line.

Although not illustrated in the drawing, the first anti-fuse may include a first program transistor MP1 and a first read transistor MR1, just as the first anti-fuse of FIG. 1 does. The second anti-fuse may include a second program transistor MP2 and a second read transistor MR2.

The first program transistor MP1 and the second program transistor MP2 are coupled with program lines, and whether the first and second program transistors MP1 and MP2 are short-circuited is decided based on whether the first and second program transistors MP1 and MP2 are programmed. The first read transistor MR1 and the second read transistor MR2 are coupled with read lines, and the first and second read transistors MR1 and MR2 output information to the bit line in the form of current that is dependent on whether the first and second program transistors MP1 and MP2 are short-circuited. The program and read operations related to this are the same as those shown in FIG. 1.

Referring to FIG. 4, the anti-fuse array may include an active region 410, a bit line contact 420, first and second program gate electrodes 430A and 430B, and first and second read gate electrodes 440A and 440B.

The active region 410 may be formed in a semiconductor substrate 400 in a first direction, and the bit line contact 420 is formed over the active region 410 to be coupled with a bit line. The first program gate electrode 430A is disposed over the first program transistor and may be formed entirely or partially buried in the active region 410. The second program gate electrode 430B is disposed over a second program transistor, and the second program gate electrode 430B may be formed entirely or partially buried in the active region 410. The first program gate electrode 430A and the second program gate electrode 430B may be formed to confront each other based on the bit line contact 420. A structure where the entire first and second program gate electrodes 430A and 430B are buried in the active region 410 is called a buried gate structure, and a structure where a portion of each of the first and second program gate electrodes 430A and 430B is buried in the active region 410 is called a recess gate structure. Additionally, the first and second program gate electrodes 430A and 430B are formed to block off the edges of the neighboring active region. The first and second program gate electrodes 430A and 430B are coupled with program lines and may receive a program voltage.

The first read gate electrode 440A is formed over a first read transistor between the first program gate electrode 430A and the bit line contact 420. The second read gate electrode 440B is formed over a second read transistor between the second program gate electrode 430B and the bit line contact 420. The first and second read gate electrodes 440A and 440B are coupled with read lines and receive a read voltage. Although not illustrated in the drawing, a gate insulation layer may be formed between the active region 410 and the first and second program gate electrodes 430A and 430B and between the semiconductor substrate 400 and the first and second read gate electrodes 440A and 440B.

The operation principles of an anti-fuse array may be described as follows. As illustrated in FIG. 1, a voltage high enough to rupture the gate insulation layer formed between the first and second program gate electrodes 430A and 430B and the active region 410 is applied to the first and second program gate electrodes 430A and 430B. The gate insulation layer may be formed of an oxide. Therefore, a channel region through which electrons may move between the source region and the drain region is formed as the gate insulation layer is ruptured. Subsequently, a read voltage that is lower than the program voltage is applied, and a signal based on whether the first and second program transistors are ruptured is transferred to the bit line BL. Therefore, information on whether the anti-fuse is programmed may be outputted from the on/off state of the read transistors.

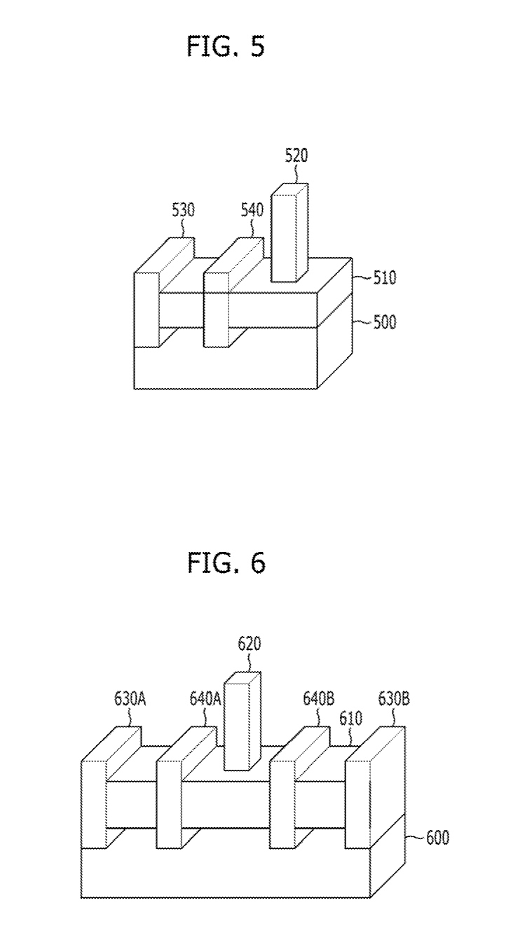

FIG. 5 is a perspective view of an anti-fuse in accordance with a second embodiment of the present invention.

Referring to FIG. 5, an active region 510 may be formed in a first direction in a semiconductor substrate 500. The bit line contact 520 is formed over the active region 510 and coupled with a bit line. The program gate electrode 530 is provided over a program transistor (not shown), and the program gate electrode 530 may be formed entirely or partially buried in the active region 510. The program gate electrode 530 is coupled with a program line and receives a program voltage. The read gate electrode 540 is formed over a read transistor between the program gate electrode 530 and the bit line contact 520. When the read gate electrode 540 is formed in the active region 510, part or the entire read gate electrode 540 may be buried in the active region 510. The read gate electrode 540 is coupled with a read line and receives a read voltage. The program gate electrode 530 and the read gate electrode 540 may have a buried gate structure where the entire gate electrode is buried in the active region 510, or a recess gate structure where part of the gate electrode is buried in the active region 510. Although not illustrated in the drawing, a gate insulation layer may be formed between the program gate electrode 530 and the neighboring active region and between the semiconductor substrate 500 and the read gate electrode 540.

As described earlier, a program operation may be performed as the gate insulation layer between the program gate electrode 530 and the active region 510 is ruptured by applying a high program voltage through the program gate electrode 530. Subsequently, when a voltage is applied to the read gate electrode 540 and turned on, a channel region through which electrons may move between a source region and a drain region is formed. The generated current is applied to the bit line contact 520, and the state of the program transistor (i.e. whether the insulator has been broken down through the program operation) may be known from the current applied from the bit line contact 520 to the bit line.

The anti-fuse in accordance with the second embodiment of the present invention has a structure where the program gate electrode 530 and the read gate electrode 540 are buried in the active region 510. The gate electrodes block off the edges of the active region 510. Since the anti-fuse of this structure may increase the area of the gate electrodes without increasing the area of the channel region for programming, the performance of a program operation may be improved. The buried gate structure may also decrease the area of an anti-fuse array in accordance with the second embodiment of the present invention. Also, loss of current that occurs when electrons move from the source region to the drain region may be reduced.

FIG. 6 is a perspective view of an anti-fuse array including the anti-fuse shown in FIG. 5.

As described earlier, the anti-fuse array may include a first anti-fuse and a second anti-fuse that confront each other based on a shared bit line.

Although not illustrated in the drawing, the first anti-fuse may include a first program transistor MP1 and a first read transistor MR1, just as the first anti-fuse of FIG. 1 does. The second anti-fuse may include a second program transistor MP2 and a second read transistor MR2.

The first program transistor MP1 and the second program transistor MP2 are coupled with program lines, respectively, and whether the first and second program transistors MP1 and MP2 are short-circuited is determined based on whether the first and second program transistors MP1 and MP2 are programmed. The first read transistor MR1 and the second read transistor MR2 are coupled with read lines, respectively, and the first and second read transistors MR1 and MR2 output information, based on whether the first program transistor MP1 and the second program transistor MP2 are short-circuited, to the bit line, in the form of current. The program and read operations related to this embodiment are the same as those discussed in relation to FIG. 1.

Referring to FIG. 6, the anti-fuse array may include an active region 610, a bit line contact 620, first and second program gate electrodes 630A and 630B, and first and second read gate electrodes 640A and 640B.

The active region 610 may be formed in the semiconductor substrate 600 in a first direction, and the bit line contact 620 may be formed over the active region 610 and coupled with a bit line. The first program gate electrode 630A is disposed over a first program transistor, and the first program gate electrode 630A may be formed partially or entirely buried in the active region 610. The second program gate electrode 630B is disposed over a second program transistor, and the second program gate electrode 630B may be formed partially or entirely buried in the active region 610. The first program gate electrode 630A and the second program gate electrode 630B may be formed to confront each other based on the bit line contact 620. The first and second program gate electrodes 630A and 630B are coupled with program lines and receive a program voltage.

The first read gate electrode 640A is formed over a first read transistor between the first program gate electrode 630A and the bit line contact 620. The first read gate electrode 640A is formed entirely or partially buried in the active region 610. Similarly, the second read gate electrode 640B is formed over a second read transistor between the second program gate electrode 630B and the bit line contact 620. The second read gate electrode 6406 may also be formed entirely or partially buried in the active region 610. The first and second read gate electrodes 640A and 646E are coupled with read lines and receive a read voltage.

The first and second program gate electrodes 630A and 630B and the first and second read gate electrodes 640A and 640B may have a buried gate structure where the entire gate electrode is buried in the active region 610, or they may have recess gate structure where part of the gate electrode is buried in the active region 610. Additionally, the first and second program gate electrodes 630A and 630B may be formed to block off the edges of the neighboring active region.

Although not illustrated in the drawing, a gate insulation layer is formed between the active region 610 and the first and second program gate electrodes 630A and 630B and between the active region 610 and the first and second read gate electrodes 640A and 640B.

The operation of the anti-fuse array is a follows. As described earlier, a program voltage high enough to rupture the gate insulation layer, formed between the first and second program gate electrodes 630A and 630B and the semiconductor substrate, is applied to the first and second program gate electrodes 630A and 630B. The gate insulation layer may be formed of an oxide. A channel region through which electrons may flow between the source region and the drain region is formed as the gate insulation layer is ruptured, Subsequently, a read voltage that is lower than the program voltage is applied, and information is transferred to the bit line BL via an electric signal that indicates whether the gates insulation layers of the first and second program transistors have been ruptured. Therefore, information on whether the anti-fuse is programmed may be outputted from the on/off state of the first and second read gate electrodes 640A and 640B.

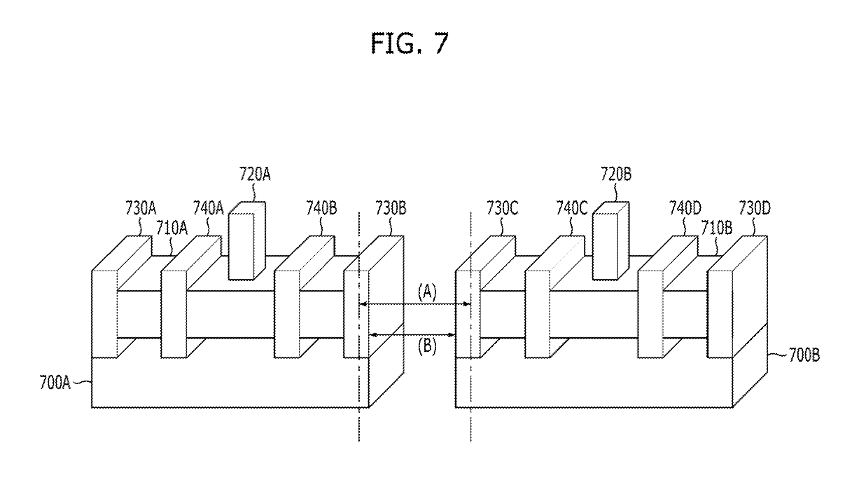

FIG. 7 is a perspective view of a plurality of anti-fuse arrays having a gate structure according to an embodiment of the present invention.

Referring to FIG. 7, a plurality of the anti-fuse arrays having the structure described in FIG. 6 is displayed.

The anti-fuse array on the left side of FIG. 7 has a structure where first and second program gate electrodes 730A and 730B and first and second read gate electrodes 740A and 740B are buried in a first active region 710A that is formed in a first semiconductor substrate 700A. The anti-fuse array on the right side of FIG. 7 has the same structure where third and fourth program gate electrodes 730C and 730D and third and fourth read gate electrodes 740C and 740D are buried in a second active region 710B in a second semiconductor substrate 700B. A gate insulation layer is provided between the gate electrodes and the active regions.

Hereafter, the effect of the anti-fuse array in accordance with the embodiments of the present invention is described. A typical anti-fuse array with a typical anti-fuse has a structure where a gate electrode is formed over a semiconductor substrate. Therefore, the edges of the active region meet the end of the gate electrode or a portion of the active region overlaps with the gate electrode because, when a voltage is applied, a channel has to be formed in the lower portion of the gate electrode. Herein, the distance between the edge of the first active region 710A and the edge of the second active region 710B is denoted as a distance (A).

The anti-fuse array in accordance with an embodiment of the present invention has a structure where the gate electrode is buried in the active region. Since the gate electrodes are buried in the active region, the gate electrodes also serve to isolate the active regions. As a result, the area of the active region may be reduced. In short, the active region requires a space equal to the distance (B) between gate electrodes. Herein, the first and second read gate electrodes 740A and 740B may be of a structure where they are formed over the semiconductor substrate instead of being buried in the active region, which was described in the first embodiment of the present invention. However, the resultant effect of the second embodiment described herein may be the same as that of the first embodiment.

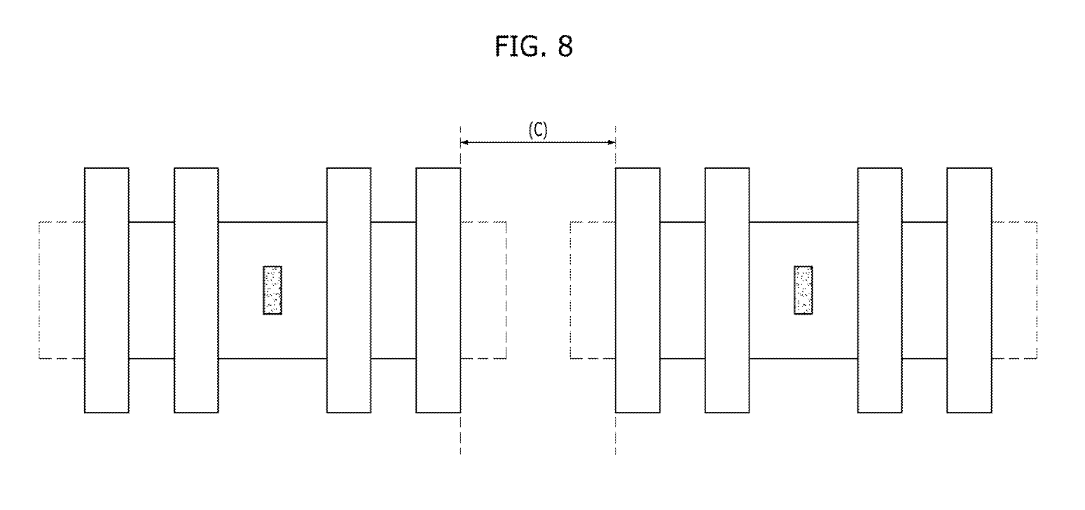

FIG. 8 is a plan view of the anti-fuse arrays shown in FIG. 7.

Referring to FIG. 8, the anti-fuse array in accordance with the embodiment of the present invention has a structure where the program gate electrodes isolate the edge the adjacent active regions, As denoted by the dotted line, the area for a dummy active region that floats in a typical anti-fuse array is not needed. Since the area for the dummy active region is not required, the distance (C) between the gate electrodes may be reduced as compared with the known technologies. As a result, the total area of the anti-fuse array may be reduced because the area of each anti-fuse has been reduced.

According to an embodiment of the present invention, an anti-fuse array includes a plurality of anti-fuses each formed to have part or the entire gate electrode structure buried in the active region. In this manner, the area of the entire anti-fuse array may be decreased.

While the present invention has been described with respect to specific embodiments, it will be apparent to those skilled in the art that various changes and modifications may be made without departing from the spirit and scope of the invention as defined in the following claims.

What is claimed is:

1. An anti-fuse comprising:
a program transistor that is capable of being short-circuited when the program transistor is programmed;
a read transistor, which is coupled with a bit line and the program transistor, that outputs information on whether the program transistor is short-circuited to the bit line;
an active region formed in a semiconductor substrate;
a bit line contact formed over the active region and coupled with the bit line;
a program gate electrode that is partially or entirely buried in the active region over the program transistor; and
a read gate electrode disposed over the read transistor and formed between the program gate electrode and the bit line contact.

2. The anti-fuse of claim 1, wherein the program gate electrode is formed to isolate the active region which is disposed adjacent thereto.

3. The anti-fuse of claim wherein the program gate electrode is coupled with a program line and receives a program voltage.

4. The anti-fuse of claim 1, wherein the read gate electrode is coupled with a read line and receives a read voltage.

5. The anti-fuse of claim 1, further comprising:
a gate insulation layer disposed between the active region and the program gate electrode and between the semiconductor substrate and the read gate electrode.

6. An anti-fuse comprising:
a program transistor that is capable of being short-circuited depending on whether the program transistor is programmed;
a read transistor, coupled with a bit line and the program transistor, that outputs information on whether the program transistor is short-circuited to the bit line;
an active region formed in a semiconductor substrate;
a bit line contact formed over the active region and coupled with the bit line;
a program gate electrode that is entirely or partially buried in the active region and over the program transistor; and
a read gate electrode, disposed over the read transistor and between the program gate electrode and the bit line contact, that is partially or entirely buried in the active region.

7. The anti-fuse of claim 6, wherein the program gate electrode is formed to cut an edge of the active region, which is disposed adjacent thereto.

8. The anti-fuse of claim 6, wherein the program gate electrode is coupled with a program line and receives a program voltage.

9. The anti-fuse of claim 6, wherein the read gate electrode is coupled with a read line and receives a read voltage.

10. The anti-fuse of claim 6, further comprising:
a gate insulation layer disposed between the active region and the program gate electrode, and between the active region and the read gate electrode.

11. An anti-fuse array comprising:
a plurality of program lines and a plurality of read lines that are arranged in a matrix with a plurality of bit lines;
first and second program transistors that are respectively coupled with the program lines and short-circuited according to whether the first and second program transistors are programmed;
first and second read transistors that are respectively coupled with the read lines, disposed between the bit lines and the first and second program transistors, and output information on whether the first and second program transistors are short-circuited to the bit lines;
active regions formed in a first direction in a semiconductor substrate;
bit line contacts formed over the active regions and coupled with the bit lines;
first and second program gate electrodes that are formed over the first and second program transistors to confront the bit line contacts, where each program gate electrode is partially or entirely buried
in a corresponding active region;
a first read gate electrode disposed over the first read transistor and formed between the first program gate electrode and a bit line contact; and
a second read gate electrode disposed over the second read transistor and formed between the second program gate electrode and the bit line contact.

12. The anti-fuse array of claim 11, wherein the first program gate electrode and the second program gate electrode are formed to cut an edge of a neighboring active region, which is disposed adjacent thereto.

13. The anti-fuse array of claim 11, wherein the first program gate electrode and the second program gate electrode are coupled with the program lines, respectively, and receive a program voltage.

14. The anti-fuse array of claim 11, wherein the first read gate electrode and the second read gate electrode are coupled with the read lines and receive a read voltage.

15. The anti-fuse array of claim 11, further comprising:
a gate insulation layer disposed between the active regions and the first and second program gate electrodes and between the semiconductor substrate and the first and second read gate electrodes.

16. An anti-fuse array comprising:
a plurality of program lines and a plurality of read lines that are arranged in a matrix with a plurality of bit lines;
first and second program transistors that are respectively coupled with the program lines and short-circuited depending on whether the first and second program transistors are programmed;
first and second read transistors that are respectively coupled with the read lines, disposed between the bit lines and the first and second program transistors, and output information on whether the first and second program transistors are short-circuited to the bit lines;
active regions formed in a semiconductor substrate;
bit line contacts formed over the active regions and coupled with the bit lines;
first and second program gate electrodes that are formed over the first and second program transistors to confront the bit line contacts, where each program gate electrode is partially or entirely buried in a corresponding active region;
a first read gate electrode disposed over the first read transistor and formed between the first program gate electrode and a bit line contact, where the first read gate electrode is partially or entirely buried in a corresponding active region; and
a second read gate electrode disposed over the second read transistor and between the second program gate electrode and the bit line contact, where the second read gate electrode is partially or entirely buried in the corresponding active region.

17. The anti-fuse array of claim 16, wherein the first program gate electrode and the second program gate electrode are formed to cut an edge of the active region, which is disposed adjacent thereto.

18. The anti-fuse array of claim 16, wherein the first and second program gate electrodes are coupled with the program lines and receive a program voltage.

19. The anti-fuse array of claim 16, wherein the first and second read gate electrodes are coupled with the read lines and receive a read voltage.

20. The anti-fuse array of claim 16, further comprising:
a gate insulation layer disposed between the active regions and the first and second program gate electrodes and between the active regions and the first and second read gate electrodes.
